(19) United States
(12) Patent Application Publication
(10) Pub. No.: US 2015/0249072 A1
(43) Pub. Date: Sep. 3, 2015

(54) Optoelectronic Component and Method for Producing an Optoelectronic Component

(71) Applicant: OSRAM Opto Semiconductors GmbH, Regensburg (DE)

(72) Inventor: Siegfried Herrmann, Neukirchen (DE)

(73) Assignee: OSRAM OPTO SEMICONDUCTORS GMBH, Regensburg (DE)

(21) Appl. No.: 14/408,952

(22) PCT Filed: May 22, 2013
(86) PCT No.: PCT/EP2013/060505

§ 371 Date: Dec. 17, 2014

(30) Foreign Application Priority Data
Jun. 27, 2012 (DE) 10 2012 105 619.6

(51) Int. Cl. H01L 25/16; H01L 23/60; H01L 29/866; H01L 29/861; H01L 33/48; H01L 33/62

(52) U.S. Cl. CPC H01L 25/167; H01L 33/486; H01L 33/62; H01L 29/866; H01L 29/861; H01L 23/60; H01L 25/165; H01L 2933/0033

(57) ABSTRACT

An optoelectronic component includes an electrically insulating connection carrier constructed in a multipartite fashion. The connection carrier has at least one ceramic layer and a silicon layer. The silicon layer has an electrically conductive layer on the top side of the silicon layer facing away from the ceramic layer. A light-emitting diode is electrically conductively and mechanically connected to the connection carrier via the electrically conductive layer. A method for producing an optoelectronic component is furthermore specified.

This patent application is a national phase filing under section 371 of PCT/EP2013/060505, filed May 22, 2013, which claims the priority of German patent application 10 2012 105 619.6, filed Jun. 27, 2012, each of which is incorporated herein by reference in its entirety.

### TECHNICAL FIELD

An optoelectronic component is specified. Furthermore, a method for producing an optoelectronic component is specified.

### SUMMARY OF THE INVENTION

Embodiments of the present application specify an optoelectronic component which is particularly stable and reliable. Further embodiments specify a method for producing a stable and reliable optoelectronic component.

In accordance with one aspect, the optoelectronic component comprises a connection carrier. The connection carrier is suitable as a carrier structure for an optoelectronic structure, preferably for a light-emitting diode (LED). The connection carrier is embodied as electrically insulating in places. The electrically insulating part of the connection carrier is formed with an electrically insulating material or with electrically insulating materials. Contact locations, plated-through holes and/or conductor tracks can be arranged into and/or onto the electrically insulating part of the connection carrier.

The electrically insulating connection carrier is embodied in the manner of a wafer, for example. In particular, the extension of the connection carrier in a lateral direction is greater than its extension in the vertical direction perpendicular thereto. In this context, “lateral direction” means a direction parallel to the main extension direction of the connection carrier. “Vertical direction” is a direction perpendicular to the main extension direction of the connection carrier, that is to say denotes for example the thickness of the connection carrier.

The connection carrier is constructed in a multipartite fashion. Preferably, the connection carrier has a bipartite construction. The connection carrier has at least one ceramic layer. Preferably, the ceramic is a low temperature co-fired ceramic (LTCC ceramic). The ceramic layer can comprise, for example, aluminum oxide (Al₂O₃), aluminum nitride (AlN), silicon nitride (SiN) or zinc oxide (ZnO). These materials have the advantage that they have very good insulation properties and also a high mechanical stability and a high thermal conductivity. The connection carrier furthermore has at least one silicon layer.

Preferably, the extension of the silicon layer in the vertical direction is less than the extension of the ceramic layer in the vertical direction. In other words, the silicon layer is made thinner than the ceramic layer. Preferably, the connection carrier has a vertical extent or thickness of at most 1 mm, for example of approximately 600 μm. Preferably, the silicon layer has a vertical extent or thickness of less than 200 μm, for example 180 μm or 150 μm. Preferably, the connection carrier, and thus also the ceramic and/or silicon layer, has a horizontal extent of approximately 100 mm.

The silicon layer and the ceramic layer are connected to one another directly, i.e. without connecting material arranged therebetween. Preferably, the connection carrier is produced by means of “silicon on ceramic” (SiCer) technology. SiCer technology is described for example in the article “SiCer—an advanced substrate for 3D integrated nano and micro systems,” ISBN 978-3-8007-3324-8, VDE Verlag GmbH, the disclosure content of which is hereby incorporated by reference. In particular, the ceramic layer and the silicon layer have preferably been connected to one another before the sintering process by means of a lamination method.

The silicon layer has an electrically conductive layer. In particular, the electrically conductive layer is arranged on the silicon layer. The electrically conductive layer is arranged on the top side of the silicon layer facing away from the ceramic layer or at least in partial regions of the top side of the silicon layer. The electrically conductive layer is a metal layer, for example. The electrically conductive layer has a small thickness. The electrically conductive layer is preferably made thinner than the silicon layer.

An optoelectronic structure, preferably an LED, is arranged on the top side of the electrically conductive layer, that is to say on the side facing away from the silicon layer. The LED is electrically conductively and mechanically connected to the connection carrier via the electrically conductive layer. Preferably, the LED is soldered in a planar fashion on the electrically conductive layer or at least on partial regions of the electrically conductive layer. The connection carrier and the optoelectric structure together form an optoelectronic semiconductor chip, and in particular an LED chip. The LED can be connected for example to MEMs (micro-electro-mechanical systems) or MOEMS (micro-optoelectro-mechanical systems).

The LED can be, in particular, a substrateless LED chip. That is to say that a growth substrate, onto which semiconductor layers of the LED chip are grown epitaxially, is removed from the epitaxially grown layers. The LED chip therefore consists of its epitaxially grown semiconductor layers and, if appropriate, of metallizations and/or insulation layers which are applied, for example, to an outer area of the semiconductor body formed by the epitaxially grown semiconductor layers. In this case, the substrateless optoelectronic LED chip is distinguished by its small thickness, inter alia. Preferably, the substrateless optoelectronic LED chip has a thickness of less than 10 μm, preferably less than 7 μm, for example approximately 6 μm.

The connection carrier formed from the silicon layer and the ceramic layer has a high mechanical stability and—in particular in the combination of the materials silicon and AlN—a high thermal conductivity. By virtue of the fact that the connection carrier has electrically insulating properties at least in places, leakage currents via the chip flanks can be avoided. A particularly stable and reliable optoelectronic component is achieved in this way.

In accordance with at least one embodiment of the optoelectronic component, the connection carrier has at least one n-side and one p-side connection location. The connection locations are arranged at the underside of the ceramic layer facing away from the silicon layer. Via the n-side connection location, electric current can be injected into the light-emitting diode fixed to the connection carrier. The n-side connection location can be, for example, the cathode of the optoelectronic component. The n-side connection location can be embodied for example as a metallization, that is to say for example as a metal layer, at the underside of the ceramic layer. The p-side connection location can be, for example, the anode of the optoelectronic component. The p-side connection location can be embodied like the n-side connection location as a metallization at the underside of the ceramic layer. The p-side connection location is electrically insulated from the n-side connection location.

Preferably, the connection carrier is suitable for surface mounting in this way by means of the n-side connection location and the p-side connection location of the connection carrier being connected for example to the contact locations of a printed circuit board on which the connection carrier is arranged. In other words, the connection carrier can be used in particular for an SMD (Surface Mounted Device) component.

In accordance with at least one embodiment of the optoelectronic component, the connection locations are electrically conductively connected to the light-emitting diode by means of in each case at least one plated-through hole. The plated-through hole enables an electrical contact-connection from that side of the connection carrier which faces away from the light-emitting diode. Consequently, a wire contact-connection or wire bonding of the light-emitting diode is not necessary.

The connection carrier has one, preferably two, three or more vertical perforations. Via said perforations, electrical contact can be made with the light-emitting diode from that side of the connection carrier which faces away from the light-emitting diode. The respective perforation extends completely through the connection carrier. In particular, the perforations completely penetrate through the silicon layer and the ceramic layer. The perforations are separated from one another. The perforations are electrically insulated from one another. The perforations in the ceramic layer are produced for example before the lamination by means of the stamping of the ceramic layer. The perforations in the silicon layer are achieved for example by means of etching of the silicon layer.

The plated-through holes provide for the electrically conductive contact of the connection locations with the assigned regions of the electrically conductive layer. By way of example, the plated-through holes are formed by metallizations of the perforations in the connection carrier. The perforations can also be filled completely with electrically conductive material, for example metal. The perforations can be filled with polysilicon, for example through the use of metal paste technology.

At the top side of the connection carrier, the plated-through holes are in direct contact with the assigned regions of the electrically conductive layer. Preferably, the electrically conductive layer is electrically conductively connected to the n-side connection location in a first region, and is electrically conductively connected to the p-side connection location in a second region. The first region and the second region of the electrically conductive layer are electrically insulated from one another. The electrically conductive layer can be formed from the same material as the plated-through holes and the connection locations, such that a region of the electrically conductive layer can be embodied integrally with the assigned plated-through holes and connection locations.

A perforation extending through the connection carrier can furthermore be used for liquid cooling of the optoelectronic component. In this case, the perforation serving for liquid cooling and the perforation serving for through-plating must be formed separately.

In accordance with at least one embodiment of the component, the connection carrier has a protective diode or a protective diode structure. By means of the protective diode structure, the light-emitting diode is protected against an electrostatic discharge. An electrical voltage, arising for example on account of electrostatic charging, said voltage being applied in the reverse direction relative to the forward direction of the active region of the light-emitting diode, can flow away via the protective diode structure. Damage to the light-emitting diode is thus avoided.

The protective diode can comprise, for example, an (electrostatic discharge, ESD) diode or a zener diode. In the case of a zener diode, the current-voltage characteristic of the protective diode structure has a threshold value in the reverse direction of the active region of the light-emitting diode. In the case of a voltage whose amplitude is less than the threshold value, no or at least no significant current flow takes place through the protective diode structure. The threshold value is preferably at least 1 V, particularly preferably at least 2 V.

The protective diode is electrically insulated from the light-emitting diode. The protective diode is electrically insulated from the connection carrier. Preferably, the protective diode is integrated in the silicon layer. By way of example, the silicon layer itself can serve as a protective diode. This can be brought about by means of a p-n-doping of the silicon layer. The silicon layer embodied as an ESD protective diode is then reverse-connected in parallel with the light-emitting diode. In particular, the p-n junctions of the light-emitting diode and of the silicon layer are reverse-connected in parallel, i.e. the p-doped region of the silicon layer is electrically conductively connected to the n-type plated-through hole and the n-doped region of the silicon layer is electrically conductively connected to the p-type plated-through hole. In this way, the light-emitting diode is protected against ESD voltage pulses that occur in the reverse direction of the p-n junction of the light-emitting diode.

As an alternative thereto, the protective diode can be introduced in an electrically insulated, vertically separated perforation of the silicon layer. In this case, the light-emitting diode is fitted on the connection carrier in such a way that the active layer of the light-emitting diode is arranged alongside or above the protective diode.

The protective diode can also be integrated in the ceramic layer of the connection carrier. Preferably, the ceramic layer forms a varistor. In this case, the ceramic layer preferably comprises ZnO as material (ZnO-based varistor). The nonlinear voltage-dependent change in the resistance of the varistor is used for protecting the light-emitting diode against overvoltage. In this case, the varistor is connected in parallel with the light-emitting diode and, by virtue of its current-voltage characteristic curve, limits the maximum voltage occurring at the light-emitting diode. The advantage of the varistor resides, in particular, in the very short response time and in the ability to absorb high energies in the event of overvoltages, without the varistor being destroyed in the process.

In accordance with at least one embodiment of the component, the ceramic layer comprises two, three or more ceramic plies. The ceramic plies are arranged parallel to the main extension direction of the connection carrier, that is to say to the lateral direction. Preferably, the ceramic layer furthermore has at least one redistribution wiring layer. The redistribution wiring layer is designed for forming electrical connections and for redistribution wiring, that is to say for electrical connection between spatially isolated contact locations. The ceramic plies and the redistribution wiring layer are arranged parallel to one another. The redistribution wiring layer is arranged in the interior of the connection carrier. In particular, the redistribution wiring layer is arranged between two ceramic plies of the ceramic layer and/or between the silicon layer and that ply of the ceramic layer which faces the silicon layer. The protective diode is connected via the redistribution wiring layer in the ceramic layer.

In accordance with at least one embodiment of the component, the connection carrier furthermore comprises a passivation layer. The passivation layer is preferably arranged at least partly on the top side of the electrically conductive layer facing away from the silicon layer. The passivation layer or the passivation material is at least partly in direct contact with the electrically conductive layer.

In accordance with at least one embodiment of the component, the component furthermore comprises an electrically conductive connecting medium layer. The connecting medium layer is arranged at least partly at the top side of the electrically conductive layer facing away from the silicon layer. The connecting medium layer is arranged between the electrically conductive layer and the light-emitting diode. The connecting medium layer is preferably a solder layer. However, the connecting medium layer can also comprise a layer composed of conductive adhesive. The connection carrier is electrically conductively and mechanically connected to the light-emitting diode by means of the connecting medium layer.

The passivation layer can be in direct contact with the electrically conductive layer exclusively in the first region. That is to say that the passivation layer is preferably arranged only where the electrically conductive layer is electrically conductively connected to the n-side connection location. In the second region of the electrically conductive layer, that is to say where the electrically conductive layer is electrically conductively connected to the p-side connection location, the connecting medium layer is then in direct contact with the electrically conductive layer. In other words, it is possible for the second region of the electrically conductive layer to be free of the passivation layer.

In accordance with a further aspect, a method for producing an optoelectronic component is described. The component produced in the process preferably corresponds to the component described above. All features disclosed for the optoelectronic component are also disclosed for the method, and vice versa.

A first step of the method involves providing a connection carrier, preferably the connection carrier described above. The connection carrier has, in particular, a ceramic layer and a silicon layer. The connection carrier is a mechanically stable and electrically insulting carrier, on the outer areas of which optoelectronic structures, preferably a light-emitting diode, can be arranged and fixed. In other words, the connection carrier is self-supporting and constitutes a stable mounting and/or carrier basis for the light-emitting diode. The connection carrier can be embodied in the manner of a wafer. Preferably, an extent of the connection carrier in the lateral direction is large relative to an extent of the connection carrier in the vertical direction. The extent of the connection carrier in the lateral direction can be, for example, at least five times greater than the extent of the connection carrier in the vertical direction.

A second step of the method involves arranging a light-emitting diode on the connection carrier. The light-emitting diode is electrically conductively connected to the electrically conductive layer of the connection carrier. Preferably, the light-emitting diode is soldered onto the connection carrier.

A third step of the method involves removing a growth substrate of the light-emitting diode. The growth substrate serves for mechanically stabilizing the light-emitting diode until the light-emitting diode is fixed to the connection carrier. After fixing, a mechanical stabilization of the light-emitting diode is no longer required, on account of the solid structure of the connection carrier, and so the growth substrate can be removed. The growth substrate can be removed for example mechanically, for instance by means of grinding, lapping or polishing, and/or chemically, for example by means of wet-chemical or dry-chemical etching and/or by means of coherent radiation, in particular laser radiation.

By means of the production method described here, an electrically insulated and mechanically very stable connection carrier is provided, with which an optoelectronic structure, and in particular a light-emitting diode, is fixedly connected. The resultant optoelectronic component has a high mechanical stability and a high reliability.

In accordance with at least one embodiment of the method, the connection carrier is laminated before the sintering of the ceramic layer. A stable, monolithic main body comprising the above-described ceramic layer and the silicon layer arises in this way.

In accordance with a further aspect a method for producing an optoelectronic component, preferably the optoelectronic component described above, is described. The component is produced by the method just described.

### BRIEF DESCRIPTION OF THE DRAWINGS

The optoelectronic component and the method are explained in greater detail below on the basis of exemplary embodiments and the associated figures.

FIG. 1 shows a perspective view of an optoelectronic component;

FIGS. 2A and 2B show a connection carrier for an optoelectronic structure;

FIG. 3 shows a connection carrier for an optoelectronic structure in accordance with the exemplary embodiment from FIGS. 2A and 2B;

FIGS. 4A and 4B show an optoelectronic component in accordance with a first exemplary embodiment; and

FIG. 5 shows an optoelectronic component in accordance with a second exemplary embodiment.

Elements that are identical, of identical type or act identically are provided with the same reference signs in the figures. The figures and the size relationships of the elements illustrated in the figures among one another should not be regarded as to scale. Rather, individual elements may be illustrated with an exaggerated size in order to enable better illustration and/or in order to afford a better understanding.

### DETAILED DESCRIPTION OF ILLUSTRATIVE EMBODIMENTS

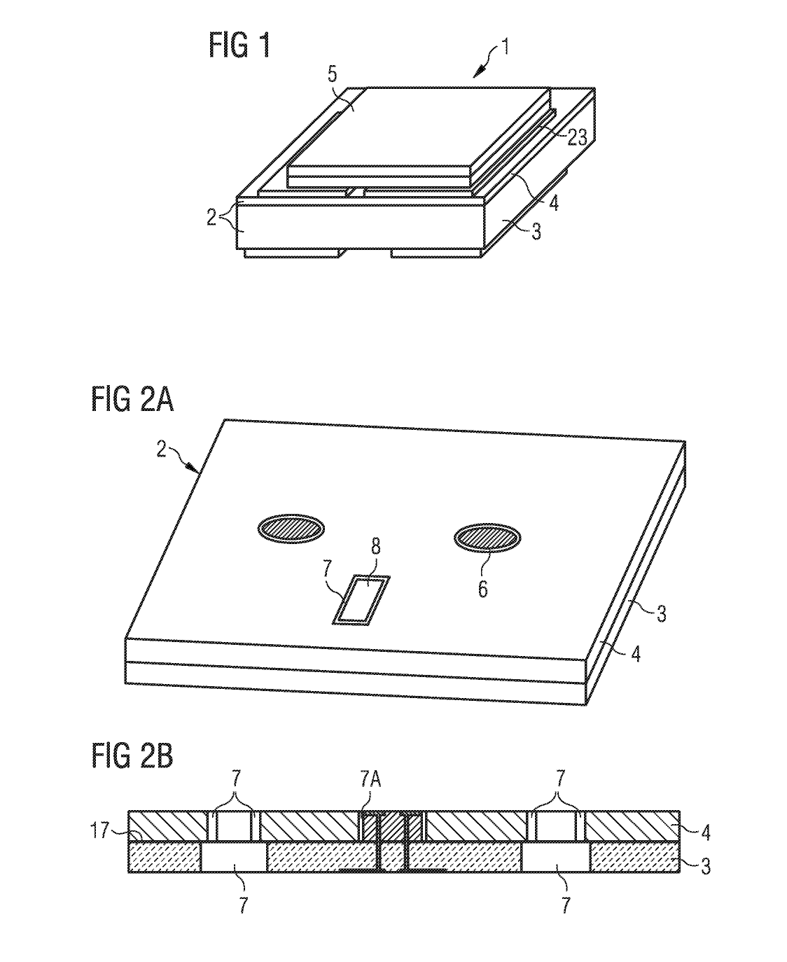

FIG. 1 shows an optoelectronic component 1 comprising a connection carrier 2. The connection carrier 2 is electrically insulating. The connection carrier 2 has a ceramic layer 3 and a silicon layer 4. The ceramic layer 3 can be an LTCC ceramic layer. The ceramic layer can comprise Al₂O₃, AlN, SiN, or ZnO.

An LED 5 is arranged on the connection carrier 2 and is mechanically stably connected thereto. The LED 5 is arranged on the top side of the silicon layer 4 facing away from the ceramic layer 3. The silicon layer 4 is arranged between the ceramic layer 3 and the LED 5.

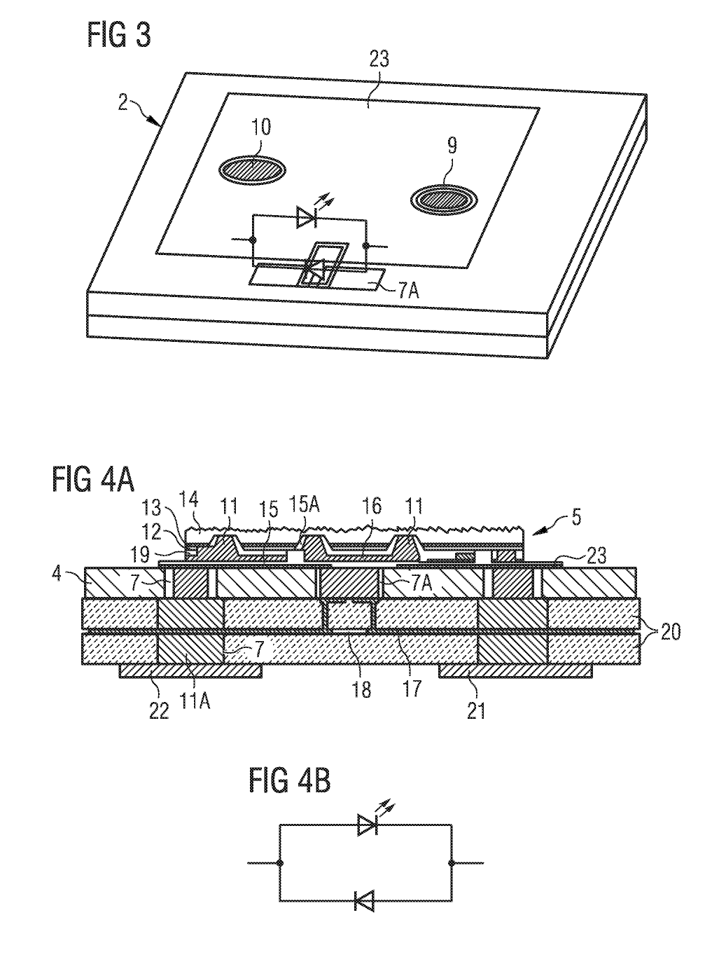

The optoelectronic component 1 furthermore comprises an electrically conductive layer 23, e.g. a metal layer. The electrically conductive layer 23 is arranged on the top side of the silicon layer 4 facing away from the ceramic layer 3. The electrically conductive layer 23 only covers parts of the top side of the silicon layer 4 (see FIGS. 1 and 3). Alternatively, the electrically conductive layer 23 can also extend completely over the top side of the silicon layer 4 (not illustrated explicitly). The electrically conductive layer 23 is arranged between the silicon layer 4 and the LED 5. The LED 5 is electrically conductively and mechanically connected to the connection carrier 2 via the electrically conductive layer 23. By way of example, the LED 5 is at least partly soldered onto the electrically conductive layer 23.

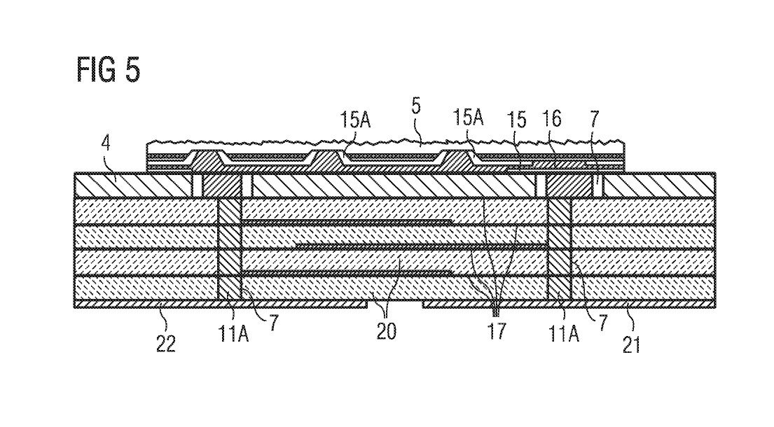

The LED 5 comprises a semiconductor layer sequence based, for example, on a III-V compound semiconductor material, as is illustrated for example in FIGS. 4A and 5. The semiconductor layer sequence comprises a p-side 12, an n-side 14 and an active layer 13 arranged therebetween. A growth substrate for the semiconductor layer sequence is completely removed (see FIGS. 4A and 5).

A mirror layer 19 is arranged at that side of the LED 5 which faces the connection carrier 2, which minor layer can consist of two or more layers. In this case, the mirror layer 19 is applied on the p-side 12 and serves for p-side contact-connection of the semiconductor layer sequence. The minor layer 19 is provided for reflecting electromagnetic radiation generated in the active region 13 of the LED 5. The mirror layer 19 is applied for example to the p-type layer 12 of the semiconductor layer sequence and is mechanically connected thereto. In this case, electric current for operating the active region 13 can also be injected into the p-side 12 of the semiconductor layer sequence via the minor layer 19, provided that the mirror layer 19 is embodied in an electrically conductive fashion. By way of example, the minor layer 19 contains a reflective material such as gold or silver.

A connecting medium layer 16 is applied to that surface of the electrically conductive layer 23 which faces away from the silicon layer 4 (see FIGS. 4A and 5). The connection carrier 2 is electrically conductively and mechanically connected to the LED 5 by means of the connecting medium layer 16. The connecting medium layer 16 contains, for example, a solder material such as gold and/or tin, for instance. The connecting medium layer 16 in places is in electrically conductive contact with the electrically conductive layer 23. In other regions, a passivation layer 15 can be arranged between the connecting medium layer 16 and the electrically conductive layer 23 (see FIGS. 4A and 5). The passivation layer 15 is electrically insulating. The passivation layer 15 can be formed with silicon dioxide and/or silicon nitride. Furthermore, the use of a ceramic material such as, for instance, aluminum oxide and/or aluminum nitride for the passivation layer 15 is possible.

The connecting medium layer 16 has an n-type region (not illustrated explicitly), which is electrically conductively connected to the n-side 14 of the semiconductor layer sequence. The connecting medium layer 16 furthermore has a p-type region (not illustrated explicitly), which is electrically conductively connected to the minor layer 19 and thereby to the p-side 12 of the semiconductor layer sequence. The mirror layer 19 is separated from the connecting medium layer 16 by a further passivation layer 15A between the mirror 19 and the connecting medium layer 16.

For the n-side contact-connection of the n-type layer 14 of the semiconductor layer sequence, the LED 5 has plated-through holes 11. The plated-through holes 11 are formed by a perforation in the semiconductor layer sequence of the LED 5. The plated-through holes 11 extend through the minor layer 19, the p-side 12 and the active layer 13 as far as the n-side 14 of the LED 5. The plated-through holes 11 are filled, for example, with material of the connecting medium layer 16 and make contact with the semiconductor layer sequence at an n-type contact 9 or n-type region 9 of the electrically conductive layer 23 (see, for example, FIGS. 3, 4A and 5), as is described in detail further below.

The connection carrier 2 has a contact region 6 (see FIG. 2A). Via the contact region 6, the LED 5 is electrically conductively connected to the connection carrier 2 via the electrically conductive layer 23. The connection carrier 2 has an n-side connection location 22 and a p-side connection location 21 (see FIG. 4A, in particular). The connection locations 21, 22 are arranged at the underside of the ceramic layer 3 facing away from the silicon layer 4, that is to say at the underside of the connection carrier 2. Via the n-side connection location 22, electric current can be injected into the LED 5 fixed to the connection carrier 2. The electrically conductive layer 23 distributes the current injected by the connection locations 21, 22 at the top side of the connection carrier 2. The p-side connection location 21 and the n-side connection location 22 are embodied for example as metallizations at the underside of the ceramic layer 3. The p-side connection location 21 and the n-side connection location 22 are electrically insulated from one another. The connection locations 21, 22 are formed for example with metals having good conductivity, such as gold, silver and/or aluminum.

The connection carrier 2 has a plurality of perforations 7 (see FIG. 2B, in particular). The perforations 7 run in the vertical direction perpendicular to the main extension direction of the connection carrier 2. The perforations 7 completely penetrate through the ceramic layer 3 and the silicon layer 4. Individual perforations 7A can also penetrate only through the silicon layer 4, which will be described in detail later. The perforations 7 are separated from one another and electrically insulated from one another.

The p- and n-side connection location 21, 22 of the connection carrier 2 is electrically conductively connected to the LED 5 by means of a respective plated-through hole 11A via the electrically conductive layer 23 and the contact region 6 (see p-contact 10 and n-type contact 9, respectively, in FIG. 3). The plated-through holes 11A can be formed by metallizations of the perforations 7 in the connection carrier 2. In an alternative exemplary embodiment, the perforations 7 are completely filled with electrically conductive material, for example metal. The metal can correspond to the metal of the electrically conductive layer 23.

The plated-through holes 11A are in direct contact with the electrically conductive layer 23 and with the p-side connection location 21 and with the n-side connection location 22. In particular, the electrically conductive layer 23 is electrically conductively connected to the n-side connection location 22 in a first region 9 (n-type contact 9), and is electrically conductively connected to the p-side connection location 21 in a second region 10 (p-type contact 10). The first region 9 and the second region 10 of the electrically conductive layer 23 are electrically insulated from one another (see FIG. 3). It is evident from FIG. 3 that the first region 9 (n-type contact 9) can be enclosed by the second region 10 (p-type contact 10). The first region 9 (n-type contact 9) is embodied in a ring-shaped fashion. In particular, the LED 5 is electrically connected on the p-side via the p-type contact 10, which is electrically conductively connected to the p-side connection location 21. The LED 5 is connected on the n-side via the n-type contact 9, which is electrically conductively connected to the n-side contact location 22.

The ceramic layer 3 can comprise a plurality of ceramic plies 20 (see FIG. 4A, for example). The ceramic plies 20 are arranged parallel to one another and to the silicon layer 4. In the exemplary embodiment shown in FIG. 4A, the ceramic layer 3 comprises two ceramic plies 20. Alternatively, the ceramic layer 3 can also comprise more than two ceramic plies 20, for example three, four or five ceramic plies 20 (see FIG. 5, for example). Alternatively, the ceramic layer 3 can also consist of a single ceramic ply, as is illustrated in FIG. 2B.

The ceramic layer 3 furthermore has a redistribution wiring layer 17. The redistribution wiring layer 17 is designed for electrical connection between spatially isolated contact locations of the optoelectronic component 1. The redistribution wiring layer 17 serves for the wiring of the component 1. The redistribution wiring layer 17 serves for connecting further electrical components in the connection carrier 2, such as a protective diode, for example, as is described in detail further below.

The redistribution wiring layer 17 is arranged in the interior of the connection carrier 2. The redistribution wiring layer 17 can be arranged between two ceramic plies 20 of the ceramic layer 3 and/or between the silicon layer 4 and the ceramic ply 20 facing the silicon layer 4. The ceramic layer 3 can have more than one redistribution wiring layer 17, for example two or three redistribution wiring layers 17 (see FIG. 5, for example).

A protective diode 8, for example an ESD diode or a zener diode, is integrated in the connection carrier 2. The protective diode 8 is electrically insulated from the LED 5. The protective diode 8 can be integrated in the silicon layer 4 (see FIG. 4A, for example). By way of example, by means of a p-n-doping of the silicon layer 4 (not illustrated explicitly), the silicon layer 4 itself can be embodied as a protective diode 8. The silicon layer 4 provided as an ESD protective diode is reverse-connected in parallel with the LED 5 in this case (see FIG. 4B).

In an alternative exemplary embodiment, the protective diode 8 can be introduced in the electrically insulated, vertically separated perforation 7A of the silicon layer 4 (see FIG. 3, for example). The protective diode 8 is connected via the redistribution wiring layer 17 in the ceramic layer 3 (see connection 18 in FIG. 4A). In this case, too, the protective diode 8 and the LED 5 are reverse-connected in parallel (see FIG. 3). The LED 5 is fitted on the connection carrier 2 in such a way that the active layer 13 of the LED 5 is arranged alongside or above the protective diode 8.

In an alternative exemplary embodiment (see FIG. 5), the protective diode can also be integrated in the ceramic layer 3. In particular, the ceramic layer 3 is embodied as an ESD protective diode in this case; in other words, the ceramic layer 3 forms a varistor. In this case, the ceramic layer 3 is preferably formed from ZnO. The ceramic layer 3 is connected in parallel with the LED 5 in this case.

The optoelectronic component 1 described above is produced as follows:

A first step involves providing the ceramic layer 3 and the silicon layer 4. By means of an etching method, the vertical perforations 7, 7A are introduced into the silicon layer. By means of a stamping method, the vertical perforations 7 are introduced in the ceramic layer 3. In a further step, the protective diode 8 can optionally be introduced into the perforation 7A of the silicon layer 4. As an alternative thereto, it is also possible, as described above, for a protective diode structure to be introduced into the ceramic layer 3 or the silicon layer 4.

The ceramic layer 3 and the silicon layer 4 are aligned with one another in a further step. In a bonding step, the ceramic layer 3 and the silicon layer 4 are connected to one another, thus giving rise to an electrically insulating, monolithic main body (connection carrier 2). In particular, the connection carrier 2 is laminated. In a next step, the ceramic layer 3 is sintered.

In a next step, the top side of the silicon layer 4 is provided with the electrically conductive layer 23. In a further step, the LED 5 is arranged on the electrically conductive layer 23 by means of the connecting material 16. In this case, an electrical connection to the protective diode structure is produced as early as when the LED 5 is connected to the connection carrier 2, such that the LED 5 is protected against damage by electrostatic discharge at an early stage during the production of the optoelectronic component 1.

A last step involves removing the growth substrate (not illustrated explicitly) of the LED 5. The LED 5 is then mechanically stabilized by means of the stable connection carrier 2.

The optoelectronic component 1 obtained is distinguished by its mechanically extremely stable connection carrier 2. Furthermore, the connection carrier 2 is embodied in an electrically insulating fashion by virtue of the choice of materials and the method for producing it. Leakage currents passing at the flanks of the component can thus be avoided. Consequently, the optoelectronic component 1 is particularly reliable and has a long lifetime.

The invention is not restricted to the exemplary embodiments by the description on the basis of said exemplary embodiments. Rather, the invention encompasses any novel feature and also any combination of features, which in particular includes any combination of features in the patent claims, even if this feature or this combination itself is not explicitly specified in the patent claims or exemplary embodiments.

1-15. (canceled)

16. An optoelectronic component, comprising:
an electrically insulating connection carrier constructed in a multipartite fashion, wherein the connection carrier includes a ceramic layer and a silicon layer;
an electrically conductive layer on a top side of the silicon layer facing away from the ceramic layer; and
a light-emitting diode electrically conductively and mechanically connected to the connection carrier via the electrically conductive layer.

17. The optoelectronic component according to claim 16, wherein the ceramic layer and the silicon layer are connected to one another without any connecting medium.

18. The optoelectronic component according to claim 16, wherein the connection carrier has an n-side connection location and a p-side connection location arranged at an underside of the ceramic layer facing away from the silicon layer.

19. The optoelectronic component according to claim 18, wherein the connection locations are each electrically conductively connected to the light-emitting diode by a plated-through hole.

20. The optoelectronic component according to claim 19, wherein each plated-through hole has vertically separated perforations that are electrically insulated, and wherein the perforations completely penetrate through the silicon layer and the ceramic layer.

21. The optoelectronic component according to claim 18, wherein the electrically conductive layer is electrically conductively connected to the n-side connection location in a first region, and is electrically conductively connected to the p-side connection location in a second region, and wherein the first region and the second region of the electrically conductive layer are electrically insulated from one another.

22. The optoelectronic component according to claim 16, further comprising a protective diode attached to the connection carrier.

23. The optoelectronic component according to claim 22, wherein the protective diode is electrically insulated from the connection carrier.

24. The optoelectronic component according to claim 22, wherein the protective diode is integrated in the silicon layer.

25. The optoelectronic component according to claim 22, wherein the ceramic layer forms a varistor, and wherein the varistor and the light-emitting diode are connected in parallel.

26. The optoelectronic component according to claim 16, wherein the ceramic layer comprises a plurality of ceramic plies.

27. The optoelectronic component according to claim 26, wherein the ceramic layer has a redistribution wiring layer arranged between two ceramic plies of the ceramic layer or between the silicon layer and that ply of the ceramic layer that faces the silicon layer.

28. The optoelectronic component according to claim 27, further comprising a protective diode that is connected via the redistribution wiring layer in the ceramic layer.

29. A method for producing an optoelectronic component, the method comprising:
providing an electrically insulating connection carrier comprising a ceramic layer and a silicon layer; and
arranging a light-emitting diode on the connection carrier, wherein the light-emitting diode is electrically conductively connected to an electrically conductive layer that is located on a top side of the silicon layer facing away from the ceramic layer.

30. The method according to claim 29, further comprising removing a growth substrate of the light-emitting diode.

31. The method according to claim 29, further comprising sintering the ceramic layers, wherein the connection carrier is laminated before sintering the ceramic layer.

32. An optoelectronic component, comprising:
an electrically insulating connection carrier that is constructed in a multipartite fashion and includes a ceramic layer and a silicon layer, wherein the ceramic layer and the silicon layer are connected to one another in a manner free of connecting medium;
an electrically conductive layer on a top side of the silicon layer facing away from the ceramic layer;
a substrateless light-emitting diode electrically conductively and mechanically connected to the connection carrier via the electrically conductive layer, wherein the connection carrier and the light-emitting diode together form an optoelectronic semiconductor chip; and
a protective diode that is integrated in the silicon layer or the ceramic layer.
